(19) United States
(12) Patent Application Publication
(10) Pub. No.: US 2015/0326221 A1
(43) Pub. Date: Nov. 12, 2015

(54) SWITCHING ELEMENT UNIT

(71) Applicant: AISIN AW CO., LTD., Anjo-shi, Aichi-ken (JP)

(72) Inventor: Hirohisa TOTANI, Yokkaichi (JP)

(21) Appl. No.: 14/409,848

(22) PCT Filed: Jul. 18, 2013
(86) PCT No.: PCT/JP2013/069492

§ 371 Date: Dec. 19, 2014

(30) Foreign Application Priority Data
Jul. 31, 2012 (JP) 2012-170193

(51) Int. Cl. H03K 17/687

(52) U.S. Cl. CPC H03K 17/687

(57) ABSTRACT

A switching element unit is implemented which can include a smoothing capacitor while achieving reduction in overall size. A smoothing capacitor is a ceramic capacitor whose dielectric portions are formed of a ceramic material, and outer surfaces of the smoothing capacitor include an element placement surface formed integrally with the dielectric portions. A positive-side connection electrode P1 that is electrically connected to a positive terminal of the smoothing capacitor and a negative-side connection electrode that is electrically connected to a negative terminal of the smoothing capacitor are formed on the element placement surface. A switching element and a diode element which form a series element unit are placed over the element placement surface, a positive-side terminal portion of the series element unit is electrically connected to the positive-side connection electrode, and a negative-side terminal portion of the series element unit is electrically connected to the negative-side connection electrode.

### I. TECHNICAL FIELD

Exemplary embodiments relate to switching element units including a switching element and a diode element.

### BACKGROUND ART

Malfunction due to switching noise needs to be prevented in semiconductor integrated circuits. Regarding prevention of such malfunction, there is a technique described in, e.g., Japanese Patent Application Publication No. H08-181445 (JP H08-181445 A) (Patent Document 1). In this section “BACKGROUND ART,” description will be given with the reference numerals of Patent Document 1 in parentheses (“[ ]”). FIG. 1 of Patent Document 1 shows that in the configuration in which an LSI chip [11] is placed on a printed wiring board [14] with a ceramic multilayer substrate [20] interposed therebetween, a capacitor portion [23] is contained in the ceramic multilayer substrate [20]. With this configuration, switching noise is filtered by the capacitor portion [23], whereby malfunction of the LSI chip [11] can be prevented, as described in paragraphs 0016 to 0017 of this document.

Some switching element units including a set of a switching element and a diode element which are electrically connected in series to each other to form a series element unit are provided with a smoothing capacitor that suppresses fluctuation in direct current (DC) voltage to be supplied to the series element unit. However, the capacitor portion [23] described in Patent Document 1 is provided in order to prevent malfunction of the LSI chip [11], and Patent Document 1 does not mention a smoothing capacitor.

### RELATED ART DOCUMENT

### Patent Document

[Patent Document 1] Japanese Patent Application Publication No. H08-181445 (JP H08-181445) (paragraphs 0016 to 0017, FIG. 1, etc.)

### II. SUMMARY

### Problem to be Solved

It is desired to implement a switching element unit that can include a smoothing capacitor while achieving reduction in overall size of the unit.

### Means for Solving the Problem

According to exemplary embodiments, a switching element unit including: at least one set of a switching element and a diode element which are electrically connected in series to each other to form a series element unit; and a smoothing capacitor that suppresses fluctuation in DC voltage to be supplied to the series element unit is characterized in that the smoothing capacitor is a ceramic capacitor whose dielectric portion interposed between electrodes is formed of a ceramic material, outer surfaces of the smoothing capacitor include an element placement surface formed integrally with the dielectric portion, a first planar surface crossing the element placement surface at an end of the element placement surface which is located on one side in a reference direction that is set along the element placement surface, and a second planar surface crossing the element placement surface at an end of the element placement surface which is located on the other side in the reference direction, a positive terminal of the smoothing capacitor is formed on the first planar surface, and a negative terminal of the smoothing capacitor is formed on the second planar surface, a positive-side connection electrode that is electrically connected to the positive terminal and a negative-side connection electrode that is electrically connected to the negative terminal are formed on the element placement surface, and the switching element and the diode element of the series element unit are placed over the element placement surface, a positive-side terminal portion of the series element unit is electrically connected to the positive-side connection electrode, and a negative-side terminal portion of the series element unit is electrically connected to the negative-side connection electrode.

According to the above characteristic configuration, the length of an electric connection path that electrically connects the series element unit and the smoothing capacitor and the length of the electric connection path in the series element unit can be reduced as compared to the case where the switching element and the diode element of the series element unit are placed so as to be separated from the smoothing capacitor. This can reduce inductance of the electric connection path, and can reduce a surge voltage (temporary increase in voltage) associated with switching operation of the switching element. As a result, power loss that causes heat generation of the switching element can be reduced according to the reduction in surge voltage, and a cooling mechanism required for heat dissipation can be simplified, whereby reduction in overall size of the unit can be achieved.

Since breakdown voltage capability required for the switching element and peripheral parts can be reduced according to the reduction in surge voltage, reduction in overall cost of the unit can also be achieved.

Moreover, according to the above characteristic configuration, since the element placement surface is formed integrally with the dielectric portion of the smoothing capacitor, the element placement surface can be formed simultaneously with the dielectric portion. In the case where the positive-side connection electrode and the negative-side connection electrode are formed of the same material as an internal electrode of the smoothing capacitor, or in the case where the positive-side connection electrode and the negative-side connection electrode are formed of a material having a melting point equal to or higher than that of the internal electrode, the positive-side connection electrode and the negative-side connection electrode can also be formed simultaneously when the dielectric portion of the smoothing capacitor is formed by, e.g., firing. This can simplify the manufacturing process of the switching element unit.

It is preferable that a positive-side internal electrode extending from the positive terminal to the negative terminal side in the reference direction and a negative-side internal electrode extending from the negative terminal to the positive terminal side in the reference direction be formed in the smoothing capacitor.

According to this configuration, the direction in which the positive-side internal electrode extends and the direction in which the negative-side internal electrode extends can be made to be parallel to the element placement surface. This facilitates reduction in overall size of the unit in the direction perpendicular to the element placement surface.

It is preferable that a direction perpendicular to the reference direction along the element placement surface be a reference perpendicular direction, and the positive-side connection electrode be configured so as not to have a portion that is placed between the negative terminal and the negative-side connection electrode in the reference direction, along an entire length in the reference perpendicular direction of the element placement surface.

According to this configuration, the length of the electric connection path that electrically connects the series element unit and the smoothing capacitor can be more easily reduced as compared to the case where the positive-side connection electrode has a portion that is placed between the negative terminal and the negative-side connection electrode in the reference direction.

It is preferable that a connection portion between the switching element and the diode element of the series element unit be an intermediate connection portion, the respective intermediate connection portions of a plurality of the series element units be electrically connected together to form a series element unit set, a direction perpendicular to the reference direction along the element placement surface be a reference perpendicular direction, and each of a plurality of the switching elements included in the same series element unit set be placed on the same side in the reference direction or on the same side in the reference perpendicular direction with respect to the diode element forming the same series element unit.

According to this configuration, the plurality of switching elements included in the same series element unit can be arranged side by side in the reference direction or the reference particular direction. This facilitates simplification of a wiring structure that electrically connects control terminals for control of the switching elements to a control unit that controls the switching elements.

It is preferable that a positive-side element placed on a positive side, which is one of the switching element and the diode element of the series element unit, be placed on the positive terminal side in the reference direction with respect to a negative-side element placed on a negative side, which is the other of the switching element and the diode element of the series element unit.

According to this configuration, the order in which the positive terminal, the negative terminal, the positive-side element, and the negative-side element are arranged in the reference direction is the same as that in the electric connection path between the positive terminal and the negative terminal. This facilitates reduction in length of the electric connection path, and simplification of a wiring structure provided other than the electrodes.

Alternatively, it is also preferable that a connection portion between a positive-side element placed on a positive side, which is one of the switching element and the diode element of the series element unit, and a negative-side element placed on a negative side, which is the other of the switching element and the diode element of the series element unit, be an intermediate connection portion, the respective intermediate connection portions of a plurality of the series element units be electrically connected together to form a series element unit set, a direction perpendicular to the reference direction along the element placement surface be a reference perpendicular direction, and each of a plurality of the positive-side elements included in the same series element unit set be placed on the same side in the reference perpendicular direction with respect to the negative-side element forming the same series element unit.

According to this configuration, the positive-side connection electrode or the negative-side connection electrode can be placed on the same side in the reference perpendicular direction for the plurality of series element units. This can simplify a wiring structure provided other than the electrodes.

In the switching element unit having each configuration described above, it is preferable that the positive-side connection electrode be formed so as to extend from the positive terminal to the negative terminal side in the reference direction on the element placement surface, the negative-side connection electrode be formed so as to extend from the negative terminal to the positive terminal side in the reference direction on the element placement surface, and an inter-element connection electrode that electrically connects the switching element and the diode element of the series element unit be formed between the positive-side connection electrode and the negative-side connection electrode in the reference direction on the element placement surface.

According to this configuration, the order in which the positive-side connection electrode, the negative-side connection electrode, and the inter-element connection electrode are arranged in the reference direction is the same as that in the electric connection path between the positive terminal and the negative terminal. This can reduce a required insulation distance between the electrodes, and can simplify a wiring structure provided other than the electrodes.

### BRIEF DESCRIPTION OF THE DRAWINGS

FIG. 1 is a perspective view of a switching element unit according to a first embodiment of the present invention.

FIG. 2 is a perspective view of the switching element unit according to the first embodiment of the present invention as viewed from a direction different from FIG. 1.

FIG. 3 is a plan view of the switching element unit according to the first embodiment of the present invention.

FIG. 4 is a sectional view taken along line IV-IV in FIG. 3.

FIG. 5 is a sectional view taken along line V-V in FIG. 3.

FIG. 6 is a plan view of a first smoothing capacitor according to the first embodiment of the present invention.

FIG. 7 is a schematic diagram showing the configuration of an inverter circuit according to the first embodiment of the present invention.

FIG. 8 is a plan view showing a first specific example of a switching element unit according to a second embodiment of the present invention.

FIG. 9 is a plan view schematically showing the first specific example of the switching element unit according to the second embodiment of the present invention.

FIG. 10 is a plan view schematically showing a second specific example of the switching element unit according to the second embodiment of the present invention.

FIG. 11 is a plan view schematically showing a first specific example of a switching element unit according to a third embodiment of the present invention.

FIG. 12 is a plan view schematically showing a second specific example of the switching element unit according to the third embodiment of the present invention.

FIG. 13 is a plan view schematically showing a third specific example of the switching element unit according to the third embodiment of the present invention.

FIG. 14 is a plan view schematically showing a fourth specific example of the switching element unit according to the third embodiment of the present invention.

FIG. 15 is a plan view schematically showing a fifth specific example of the switching element unit according to the third embodiment of the present invention.

FIG. 16 is a plan view schematically showing a sixth specific example of the switching element unit according to the third embodiment of the present invention.

FIG. 17 is a plan view schematically showing a seventh specific example of the switching element unit according to the third embodiment of the present invention.

FIG. 18 is a plan view schematically showing an eighth specific example of the switching element unit according to the third embodiment of the present invention.

FIG. 19 is a plan view schematically showing a first specific example of a switching element unit according to a fourth embodiment of the present invention.

FIG. 20 is a plan view schematically showing a second specific example of the switching element unit according to the fourth embodiment of the present invention.

FIG. 21 is a plan view schematically showing a third specific example of the switching element unit according to the fourth embodiment of the present invention.

### BEST MODES

### 1. First Embodiment

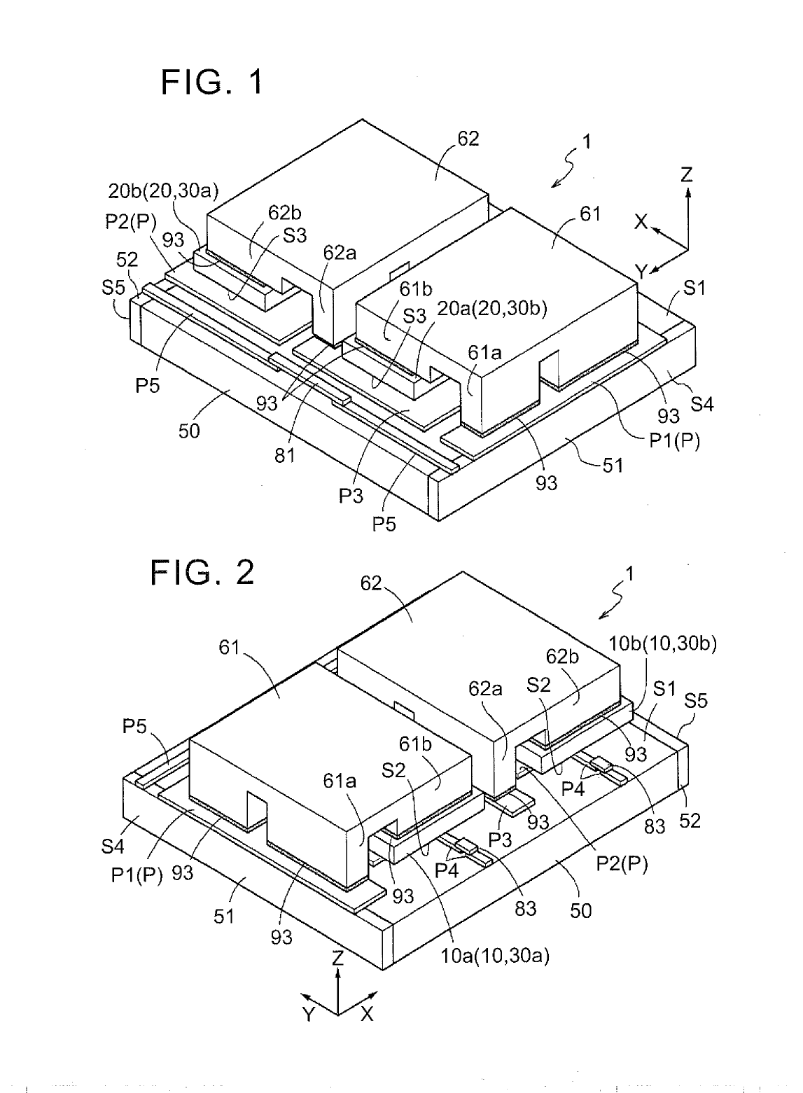

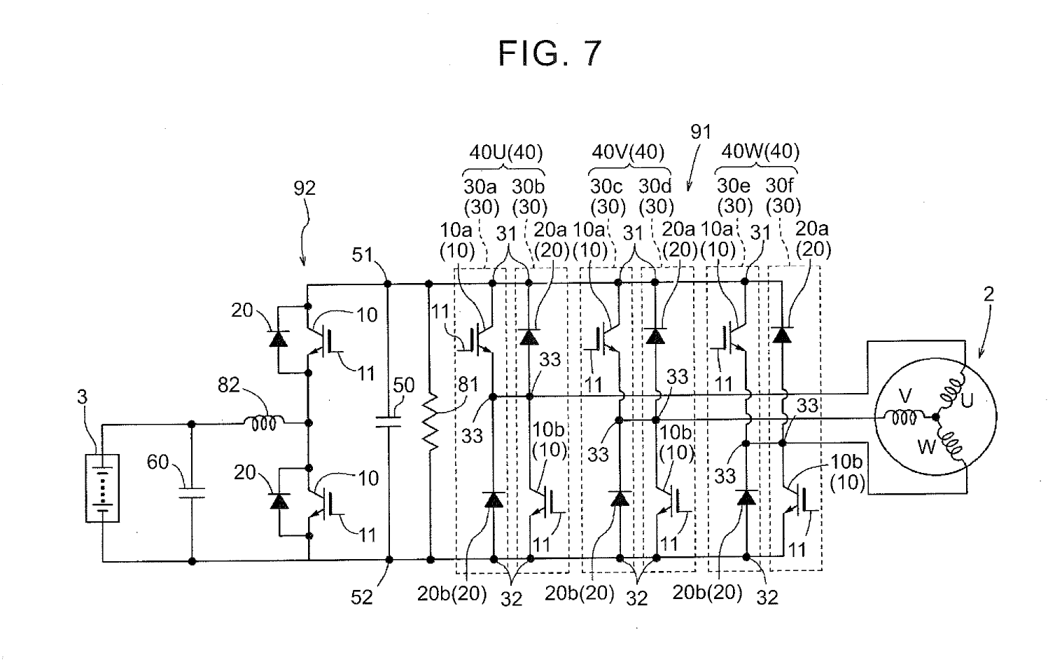

A first embodiment will be described with reference to FIGS. 1 to 7. A switching element unit according to an exemplary embodiment is herein described with respect to an example in which the switching element unit is applied to an inverter circuit 91 (see FIG. 7) that controls a rotating electrical machine 2. That is, in the present embodiment, a switching element 10 and a diode element 20 which form the switching element unit 1 are electronic elements that form the inverter circuit 91, and the switching element 10 is an electronic element that carries out power conversion between direct current (DC) power and alternating current (AC) power.

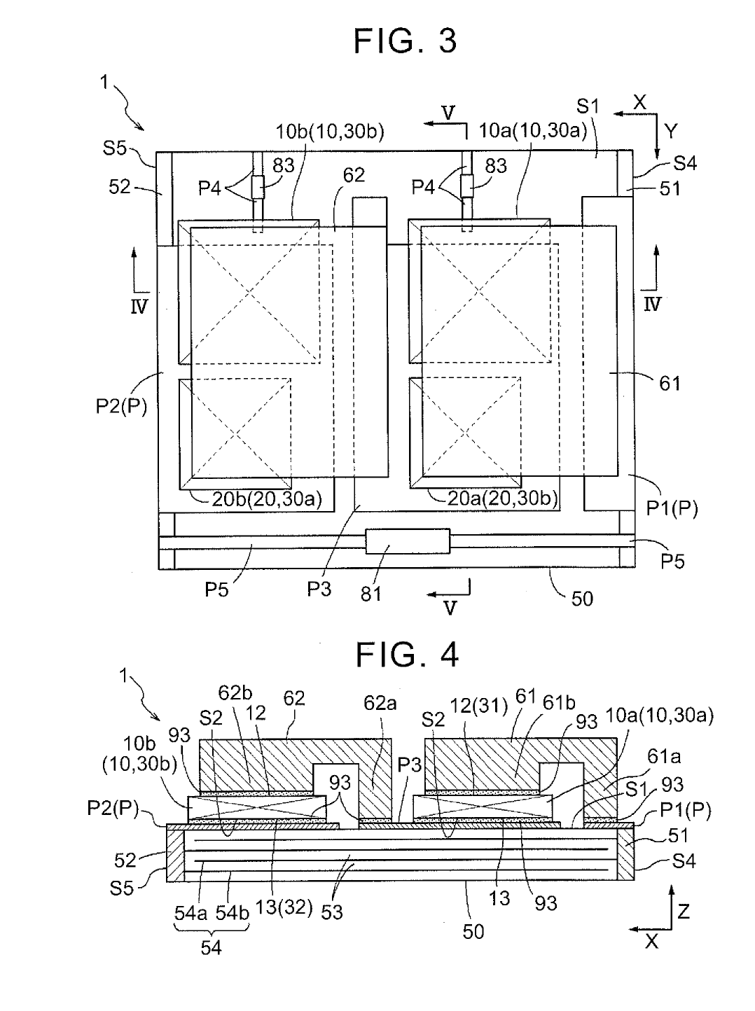

In the following description, the term “upper” refers to the “+Z direction” in FIG. 1 and the term “lower” refers to the “−Z direction” in FIG. 1 unless otherwise specified. The Z direction is a direction perpendicular to an element placement surface S1 as shown in FIG. 4, and the Z direction from the element placement surface S1 toward the switching element 10 placed over the element placement surface S1 is positive. That is, the +Z direction matches the direction of a normal vector to the element placement surface S1. The X direction is a reference direction that is set along the element placement surface S1, and as shown in FIG. 3, the X direction from a positive terminal 51 toward a negative terminal 52 of a first smoothing capacitor 50 is positive. The Y direction is a reference perpendicular direction perpendicular to the reference direction (X direction) along the element placement surface S1. The orientation of the Y direction (positive/negative) is defined so that the X direction, the Y direction, and the Z direction form a right-handed rectangular coordinate system in this order, as shown in FIG. 1.

1-1. General Configuration of Switching Element Unit

As shown in FIGS. 1 to 3, the switching element unit 1 includes a switching element 10, a diode element 20, and a first smoothing capacitor 50. The switching element 10 and the diode element 20 which are included in the switching element unit 1 are electrically connected in series to each other to form a series element unit 30, as shown in FIG. 7. The switching element unit 1 includes at least one set of the switching element 10 and the diode element 20 which forms the series element unit 30 (hereinafter referred to as the “electronic element set”). In the present embodiment, as shown in FIG. 3, the switching element unit 1 includes a plurality of electronic element sets. Specifically, the switching element unit 1 includes two electronic element sets, namely an electronic element set forming a first series element unit 30a and an electronic element set forming a second series element unit 30b.

The first smoothing capacitor 50 is a circuit component that suppresses fluctuation in DC voltage to be supplied to the series element units 30 (i.e., smooths the DC voltage). In the present embodiment, as shown in FIG. 7, a rotating electrical machine drive circuit that drives the rotating electrical machine 2 includes a booster circuit 92 in addition to the inverter circuit 91. As a smoothing capacitor, a second smoothing capacitor 60 is included in the rotating electrical machine drive circuit in addition to the first smoothing capacitor 50. The booster circuit 92 is a circuit that boosts the DC voltage of a DC power supply 3, and includes two switching elements 10, a total of two diode elements 20 electrically connected in parallel to the two switching elements 10 and a reactor 82. Energy is intermittently stored in the reactor 82 according to switching of the switching elements 10. The DC power supply 3 is formed by, e.g., a battery, a capacitor, etc. In the present embodiment, the first smoothing capacitor 50 corresponds to the “smoothing capacitor.”

The first smoothing capacitor 50 is electrically connected in parallel to the DC side of the inverter circuit 91 to suppress fluctuation in DC voltage to be supplied to the series element units 30 of the inverter circuit 91. That is, the first smoothing capacitor 50 suppresses fluctuation in DC voltage to be supplied to the switching elements 10 of the series element units 30. A discharge resistor 81 that releases charge stored in the first smoothing capacitor 50 when the power is off etc. is electrically connected in parallel to the first smoothing capacitor 50. The second smoothing capacitor 60 is electrically connected in parallel to the DC power supply 3 to suppress fluctuation in DC voltage to be supplied to the switching elements 10 of the booster circuit 92. That is, the first smoothing capacitor 50 is a post-boost smoothing capacitor that smooths the voltage that has been boosted by the booster circuit 92, and the second smoothing capacitor 60 is a pre-boost smoothing capacitor that smooths the voltage that has not been boosted by the booster circuit 92.

As shown in FIG. 1 etc., the outer surfaces of the first smoothing capacitor 50 include a planar element placement surface S1, a first planar surface S4, and a second planar surface S5. As shown in FIGS. 3 and 4, the first planar surface S4 is a surface that crosses the element placement surface S1 at the end of the element placement surface S1 which is located on the −X direction side as one side of the X direction. The second planar surface S5 is a surface that crosses the element placement surface S1 at the end of the element placement surface S1 which is located on the +X direction side as the other side of the X direction. The first planar surface S4 and the second planar surface S5 are formed so as to face opposite directions from each other. Regarding two surfaces, the expression “face opposite directions from each other” means that the inner product of respective outward pointing normal vectors to the surfaces is negative, and includes the case where the first planar surface S4 and the second planar surface S5 cross each other. The element placement surface S1 is formed on the upper surface (surface facing the +Z direction) as the upper outer surface of the first smoothing capacitor 50. In the present embodiment, the first smoothing capacitor 50 has a rectangular parallelepiped outer shape, each of the element placement surface S1, the first planar surface S4, and the second planar surface S5 is formed in a rectangular shape, and each of the first planar surface S4 and the second planar surface S5 is formed as a surface perpendicular to the element placement surface S1. That is, in the present embodiment, the first planar surface S4 and the second planar surface S5 are formed as surfaces facing opposite directions from each other and parallel to each other.

As shown in FIG. 1 etc., a terminal connection electrode P (specifically, a positive-side connection electrode P1 and a negative-side connection electrode P2) as an electrode that is electrically connected to a terminal of the first smoothing capacitor 50 is formed on the element placement surface S1. The switching elements 10 and the diode elements 20 of the series element units 30 are placed (that is, mounted) over the element placement surface S1 so as to be electrically connected to the terminal connection electrode P. These switching elements 10 and these diode elements 20 are placed (i.e., mounted) over the element placement surface S1 from above. The terminal connection electrode P that is formed on the element placement surface S1, and an inter-element connection electrode P3, a control electrode P4, and a discharge resistor electrode P5 (see FIG. 6) which are described below can be electrodes formed of, e.g., conductive foil (copper foil). Such electrodes can be formed on the element placement surface S1 by using, e.g., a printing technique.

The first smoothing capacitor 50 includes a positive terminal 51 as a terminal on the positive side, and a negative terminal 52 as a terminal on the negative side. As shown in FIG. 7, these terminals 51, 52 function as terminals that receive and output DC power from and to the DC power supply 3 and the booster circuit 92, and also function as terminals that receive and output DC power from and to the inverter circuit 91. In the present embodiment, as shown in FIG. 4, the positive terminal 51 is formed on the first planar surface S4 placed at the end on the −X direction side of the first smoothing capacitor 50, and the negative terminal 52 is formed on the second planar surface S5 placed at the end on the +X direction side of the first smoothing capacitor 50. In the present embodiment, both the positive terminal 51 and the negative terminal 52 are formed so as to be exposed from the upper surface of the first smoothing capacitor 50. That is, in the present embodiment, the upper surface of the first smoothing capacitor 50 includes a portion formed by the upper end of the positive terminal 51 and a portion formed by the upper end of the negative terminal 52. Moreover, in the present embodiment, as shown in FIGS. 1 to 3, the positive terminal 51 and the negative terminal 52 are formed so as to be exposed from both side surfaces in the Y direction (lateral outer surfaces) of the first smoothing capacitor 50, respectively.

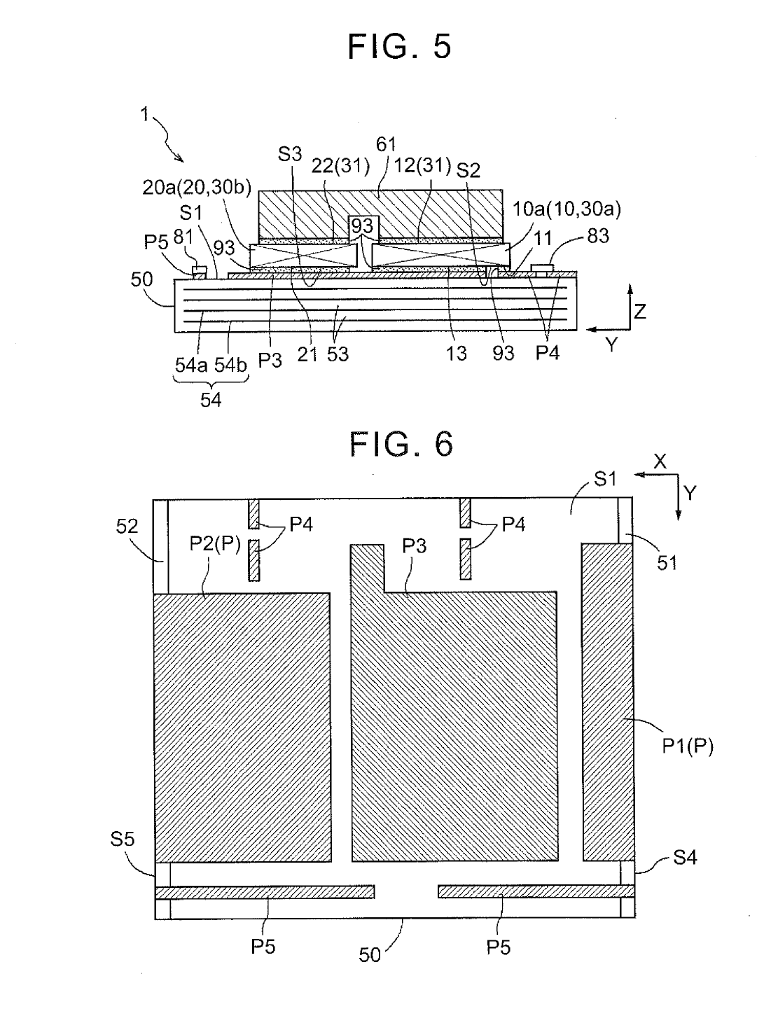

The first smoothing capacitor 50 is a ceramic capacitor whose dielectric portions 53 interposed between electrodes are formed of a ceramic material. This ceramic material is comprised of, e.g., barium titanate, strontium titanate, etc. Specifically, as schematically shown in FIGS. 4 and 5, the first smoothing capacitor 50 is a stacked ceramic capacitor, and has a structure in which the dielectric portions 53 are stacked in a stacking direction (in this example, the vertical direction) with an internal electrode 54 interposed therebetween. In the internal electrode 54, a positive-side internal electrode 54a electrically connected to the positive terminal 51 and a negative-side internal electrode 54b electrically connected to the negative terminal 52 are alternately arranged in the stacking direction. The positive-side internal electrode 54a is formed so as to extend from the positive terminal 51 to the +X direction side in the first smoothing capacitor 50. The negative-side internal electrode 54b is formed so as to extend from the negative terminal 52 to the −X direction side in the first smoothing capacitor 50. That is, both the positive terminal 51 and the negative terminal 52 function as external electrodes and are formed so as to extend along the entire length in the stacking direction of the first smoothing capacitor 50. Although the number of stacked dielectric portions 53 is “5” in FIGS. 4 and 5, any number of dielectric portions 53 may be stacked in actual implementations. For example, a smoothing capacitor having 100 or more stacked dielectric portions 53 may be used as the first smoothing capacitor 50.

The element placement surface S1 that is formed on the outer surface of the first smoothing capacitor 50 is formed integrally with the dielectric portions 53. Specifically, in the present embodiment, the upper surface (specifically, a portion other than the terminals 51, 52) of the first smoothing capacitor 50 is formed by the dielectric portion 53 placed at the upper end, and the lower surface (specifically, a portion other than the terminals 51, 52) serving as the lower outer surface of the first smoothing capacitor 50 is formed by the dielectric portion 53 placed at the lower end. That is, in the present embodiment, the upper surface (specifically, the portion other than the terminals 51, 52 in the upper surface) of the first smoothing capacitor 50 on which the element placement surface S1 is formed and the lower surface (specifically, the portion other than the terminals 51, 52 in the lower surface) of the first smoothing capacitor 50 are formed of the same material as the dielectric portions 53 and integrally with the dielectric portions 53. Such a first smoothing capacitor 50 may be, e.g., a smoothing capacitor manufactured by low temperature co-firing by using low temperature co-fired ceramics (LTCC) technology.

1-2. Arrangement Configuration of Series Element Unit

The arrangement configuration of the series element units 30 in the switching element unit 1 will be described below. As shown in FIG. 3, in the present embodiment, the two series element units 30, namely the first series element unit 30a and the second series element unit 30b, are placed on the element placement surface S1. As shown in FIG. 7, respective intermediate connection portions 33 of the two series element units 30 are electrically connected together to form a series element unit set 40.

As shown in FIG. 7, the series element unit 30 includes a positive-side terminal portion 31 that is connected to the positive side of the DC power supply 3, and a negative-side terminal portion 32 that is connected to the negative side (e.g., the ground side) of the DC power supply 3. In the present embodiment, the positive-side terminal portion 31 of the series element unit 30 is electrically connected to a positive electrode of the DC power supply 3 via the switching element 10 and the reactor 82 of the booster circuit 92, so that a DC voltage boosted by the booster circuit 92 is supplied to the positive-side terminal portion 31 of the series element unit 30.

The series element unit set 40 formed by the series element units 30 forms a single arm set (a set of an upper stage arm and a lower stage arm; in other words, a leg) of the inverter circuit 91 that converts a DC voltage to an AC voltage. A plurality of series element units 30 forming the same arm set are included in the same switching element unit 1. In the present embodiment, two series element units 30 forming a single arm set are included in the same switching element unit 1 and are placed on the same element placement surface S1. That is, in the present embodiment, the switching element unit 1 includes a single series element unit set 40.

In the present embodiment, as shown in FIG. 7, the rotating electrical machine 2 to which an AC voltage is supplied is an AC motor that is driven by three-phase AC power, and a total of three arm sets respectively corresponding to three phases (U-phase, V-phase, and W-phase) are electrically connected in parallel to form the inverter circuit 91. That is, in the present embodiment, the inverter circuit 91 is formed by using a switching element unit including a V-phase series element unit set 40V and a switching element unit including a W-phase series element unit set 40W in addition to the switching element unit 1 including the U-phase series element unit set 40U. The V-phase series element unit set 40V and the W-phase series element unit set 40W are configured similarly to the U-phase series element unit set 40U except the connection relationship with the rotating electrical machine 2 (specifically, the phase of a coil to which the series element unit set is connected). Accordingly, the switching element unit including the V-phase series element unit set 40V and the switching element unit including the W-phase series element unit set 40W are not shown in the figures.

In the present embodiment, the inverter circuit 91 is thus formed by the three switching element units. To each arm set (each series element unit set 40), one first smoothing capacitor 50 is electrically connected in parallel. In order to avoid complication, FIG. 7 shows an example in which a single first smoothing capacitor 50 is connected to all the three arm sets. The rotating electrical machine 2 that is controlled by the inverter circuit 91 can be, e.g., a rotating electrical machine that is provided as a driving force source of wheels in electric vehicles, hybrid vehicles, etc. In the specification, the term “rotating electrical machine” is used as a concept including all of a motor (electric motor), a generator (electric generator), and a motor-generator that functions as both a motor and a generator as necessary.

As shown in FIG. 7, the positive-side terminal portion 31 of the series element unit 30 is electrically connected to the positive-side connection electrode P1 (see FIG. 6), and is thus electrically connected to the positive terminal 51 of the first smoothing capacitor 50. The negative-side terminal portion 32 of the series element unit 30 is electrically connected to the negative-side connection electrode P2 (see FIG. 6), and is thus electrically connected to the negative terminal 52 of the first smoothing capacitor 50. The respective intermediate connection portions 33 of the plurality of (in this example, two) series element units 30 forming the same series element unit set 40 are electrically connected to each other, and are connected to the coil of a corresponding phase. The configuration of the switching element unit 1 that implements such an electric connection configuration will be described below.

As described above, the terminal connection electrode P electrically connected to the terminals 51, 52 of the first smoothing capacitor 50 is formed on the element placement surface S1. Specifically, as shown in FIG. 6, the positive-side connection electrode P1 electrically connected to the positive terminal 51 and the negative-side connection electrode P2 electrically connected to the negative terminal 52 are formed on the element placement surface S1 as the terminal connection electrode P. In the present embodiment, the discharge resistor electrode P5 having both a portion electrically connected to the positive terminal 51 and a portion electrically connected to the negative terminal 52 is further formed on the element placement surface S1. Each of the positive-side connection electrode P1 and the portion of the discharge resistor electrode P5 which is electrically connected to the positive terminal 51 is formed so as to cover a part of the upper surface of the positive terminal 51, thereby forming the electric connection with the positive terminal 51. Each of the negative-side connection electrode P2 and the portion of the discharge resistor electrode P5 which is electrically connected to the negative terminal 52 is formed so as to cover a part of the upper surface of the negative terminal 52, thereby forming the electric connection with the negative terminal 52.

The positive-side connection electrode P1 and the negative-side connection electrode P2 are electrodes that electrically connect the switching elements 10 and the diode elements 20 to the first smoothing capacitor 50. In the present embodiment, connection portions to the inverter circuit 91 side in the external electrodes of the first smoothing capacitor 50 are formed by the upper surfaces of the positive terminal 51 and the negative terminal 52. Although detailed description is omitted, connection portions to the DC power supply 3 side in the external electrodes of the first smoothing capacitor 50 can also be formed by the upper surfaces of the positive terminal 51 and the negative terminal 52. The connection portions to the DC power supply 3 side in the external electrodes of the first smoothing capacitor 50 may be formed by the side or lower surfaces of the positive terminal 51 and the negative terminal 52.

As shown in FIG. 6, the inter-element connection electrode P3 and the control electrode P4 are formed on the element placement surface S1 in addition to the above three electrodes P1, P2, P5. These electrodes P3, P4 are electrodes that are electrically isolated from the terminals 51, 52 of the first smoothing capacitor 50. As used herein, the expression “electrically isolated” means being electrically isolated on the element placement surface S1, and is used as a concept including the case of being electrically connected to the terminals 51, 52 of the first smoothing capacitor 50 via a circuit element, a wiring member, etc. placed on the element placement surface S1.

As shown in FIG. 6, in the present embodiment, the positive-side connection electrode P1 is formed so as to extend from the positive terminal 51 to the negative terminal 52 side (i.e., the +X direction side) in the X direction on the element placement surface S1, and the negative-side connection electrode P2 is formed so as to extend from the negative terminal 52 to the positive terminal 51 side (i.e., the −X direction side) in the X direction on the element placement surface S1. In the present embodiment, the positive-side connection electrode P1 is configured so as not to have a portion that is placed between the negative terminal 52 and the negative-side connection electrode P2 in the X direction, along the entire length in the Y direction of the element placement surface S1. Specifically, each of the positive-side connection electrode P1 and the negative-side connection electrode P2 is formed in a rectangular shape as viewed in the Z direction, and each of the length in the X direction of the positive-side connection electrode P1 and the length in the X direction of the negative-side connection electrode P2 is set so that the positive-side connection electrode P1 and the negative-side connection electrode P2 are separated from each other in the X direction. The inter-element connection electrode P3 that electrically connects the switching element 10 and the diode element 20 of the series element unit 30 is formed between the positive-side connection electrode P1 and the negative-side connection electrode P2 in the X direction on the element placement surface S1.

In the present embodiment, as shown in FIG. 6, the positive-side connection electrode P1, the negative-side connection electrode P2, and the inter-element connection electrode P3 are formed so as to have a portion where the electrodes P1, P2, P3 overlap each other, as viewed in the X direction. That is, there is a region in the Y direction which is included in all of three regions, namely a region in the Y direction where the positive-side connection electrode P1 is formed, a region in the Y direction where the negative-side connection electrode P2 is formed, and a region in the Y direction where the inter-element connection electrode P3 is formed, and the inter-element connection electrode P3 is formed so as to be interposed between the positive-side connection electrode P1 and the negative-side connection electrode P2 from both sides in the X direction. The inter-element connection electrode P3 is formed in a rectangular shape as viewed in the Z direction. In this example, in a part on the +X direction side of the inter-element connection electrode P3 where a second connection member 62 (described below) is placed, the inter-element connection electrode P3 has a portion protruding to the −Y direction side with respect to the rectangular portion, as shown in FIG. 3.

Although the switching element 10 and the diode element 20 are electrically connected in series to each other in both the first series element unit 30a and the second series element unit 30b, the arrangement configuration of the switching element 10 and the diode element 20 is different between the first series element unit 30a and the second series element unit 30b, as shown in FIG. 7. Specifically, the positive-side element of the first series element unit 30a is the switching element 10, whereas the positive-side element of the second series element unit 30b is the diode element 20. The negative-side element of the first series element unit 30a is the diode element 20, whereas the negative-side element of the second series element unit 30b is the switching element 10. As used herein, the “positive-side element” refers to the element that is placed on the positive side in the series element unit 30, and the “negative-side element” refers to the element that is placed on the negative side in the series element unit 30.

The first series element unit 30a and the second series element unit 30b are electrically connected to each other at their respective intermediate connection portions 33. In this case, the intermediate connection portion 33 is the connection portion between the positive-side element and the negative-side element (in other words, the connection portion between the switching element 10 and the diode element 20) of the series element unit 30. Accordingly, the element set of the positive-side element of the first series element unit 30a and the positive-side element of the second series element unit 30b which are electrically connected in parallel to each other and the element set of the negative-side element of the first series element unit 30a and the negative-side element of the second series element unit 30b which are electrically connected in parallel to each other are electrically connected in series to each other to form the series element unit set 40. That is, an upper stage-side switching element 10a to which an upper stage-side diode element 20a is electrically connected in parallel and a lower stage-side switching element 10b to which a lower stage-side diode element 20b is electrically connected in parallel are electrically connected in series to each other to form the series element unit set 40. As used herein, the “upper stage-side switching element 10a” and the “upper stage-side diode element 20a” are the switching element 10 and the diode element 20 which are placed in the upper stage arm in the inverter circuit shown in FIG. 7, respectively, and the “lower stage-side switching element 10b” and the “lower stage-side diode element 20b” are the switching element 10 and the diode element 20 which are placed in the lower stage arm in the inverter circuit, respectively.

As shown in FIG. 3, in the present embodiment, the upper stage-side switching element 10a is placed on the −Y direction side with respect to the lower stage-side diode element 20b, and the lower stage-side switching element 10b is placed on the −Y direction side with respect to the upper stage-side diode element 20a. That is, each of the plurality of switching elements 10 included in the same series element unit set 40 is placed on the same side in the Y direction with respect to the diode element 20 of the same series element unit 30. The plurality of switching elements 10 included in the same series element unit set 40 (in this example, the upper stage-side switching element 10a and the lower stage-side switching element 10b) are arranged side by side in the X direction over the element placement surface S1. In the present embodiment, as shown in FIG. 6, the element placement surface S1 is formed in a rectangular shape having a longer side and a shorter side. The X direction is parallel to the direction in which the longer side extends, and the Y direction is parallel to the direction in which the shorter side extends. The diode element 20 that is electrically connected in parallel to the switching element 10 is placed over the element placement surface S1 so as to be located next to this switching element 10 in the Y direction. Specifically, the upper stage-side diode element 20a is placed so as to adjoin the +Y direction side of the upper stage-side switching element 10a, and the lower stage-side diode element 20b is placed so as to adjoin the +Y direction side of the lower stage-side switching element 10b. As used herein, the expression “placed so as to adjoin” means no other circuit element is placed between the switching element 10 and the diode element 20 in the direction in which the element placement surface S1 extends (in this example, the Y direction), and is used as a concept including both the state where the separation distance between the switching element 10 and the diode element 20 is zero (i.e., the state where their respective outer surfaces contact each other) and the state where this separation distance is larger than zero.

The upper stage-side switching element 10a, the lower stage-side switching element 10b, the upper stage-side diode element 20a, and the lower stage-side diode element 20b are arranged as described above. Accordingly, in the present embodiment, as shown in FIG. 3, the upper stage-side switching element 10a is placed on the −X direction side with respect to the lower stage-side diode element 20b, and the upper stage-side diode element 20a is placed on the −X direction side with respect to the lower stage-side switching element 10b. That is, in the present embodiment, in each of the first series element unit 30a and the second series element unit 30b, the positive-side element placed on the positive side, which is one of the switching element 10 and the diode element 20 of the series element unit 30, is placed on the −X direction side (i.e., the positive terminal 51 side in the X direction) with respect to the negative-side element placed on the negative side, which is the other of the switching element 10 and the diode element 20 of the series element unit 30.

As shown in FIGS. 4 and 5, the switching element 10 has a pair of main terminals 12, 13 and a control terminal 11. The main terminals 12, 13 are terminals that are electrically connected to a supply source of a DC voltage (in this example, the DC power supply 3). Of the main terminals 12, 13, the terminal on the high potential side is the positive-side main terminal 12, and the terminal on the low potential side is the negative-side main terminal 13. As shown in FIGS. 5 and 7, the upper stage-side diode element 20a is electrically connected in anti-parallel relation to the upper stage-side switching element 10a such that a cathode terminal 22 is electrically connected to the positive-side main terminal 12 of the upper stage-side switching element 10a, and an anode terminal 21 is electrically connected to the negative-side main terminal 13 of the upper stage-side switching element 10a. The lower stage-side diode element 20b is similarly electrically connected in anti-parallel relation to the lower stage-side switching element 10b. That is, the diode element 20 functions as a free wheel diode (FWD). The control terminal 11 is a control terminal that performs on-off control of the switching element 10. In the on state of the switching element 10, the positive-side main terminal 12 and the negative-side main terminal 13 are electrically connected to each other. In the off state of the switching element 10, the positive-side main terminal 12 and the negative-side main terminal 13 are electrically disconnected from each other.

As shown in FIGS. 4, 5, and 7, the positive-side main terminal 12 of the upper stage-side switching element 10a forms the positive-side terminal portion 31 of the first series element unit 30a, and the anode terminal 21 of the lower stage-side diode element 20b forms the negative-side terminal portion 32 of the first series element unit 30a. The negative-side main terminal 13 of the lower-stage side switching element 10b forms the negative-side terminal portion 32 of the second series element unit 30b, and the cathode terminal 22 of the upper stage-side diode element 20a forms the positive-side terminal portion 31 of the second series element unit 30b.

In the present embodiment, as shown in FIG. 7, the switching element 10 is an insulated gate bipolar transistor (IGBT), the positive-side main terminal 12 is constituted by a collector terminal, the negative-side main terminal 13 is formed by an emitter terminal, and the control terminal 11 is formed by a gate terminal. The control terminal 11 is electrically connected to a control unit, not shown, via a gate resistor 83 (see FIGS. 3 and 5), and switching of each switching element 10 is individually controlled according to the gate voltage that is applied to the control terminal 11. A metal oxide semiconductor field effect transistor (MOSFET) etc. may be used as the switching element 10.

As shown in FIG. 5, the positive-side main terminal 12 and the negative-side main terminal 13 are separately formed on the outer surfaces facing opposite sides from each other in the switching element 10 having a rectangular parallelepiped outer shape. Specifically, the switching element 10 has an outer surface having the positive-side main terminal 12 formed thereon and an outer surface having the negative-side main terminal 13 formed thereon, and these two outer surfaces are formed as surfaces facing opposite directions from each other and parallel to each other. The switching element 10 is placed over the element placement surface S1 so that its outer surface having the negative-side main terminal 13 formed thereon serves as a first counter placement surface S2 facing the element placement surface S1. That is, in the state where the switching element 10 is placed over the element placement surface S1, the positive-side main terminal 12 is located on the upper surface of the switching element 10, and the negative-side main terminal 13 is located on the lower surface of the switching element 10. In the present embodiment, the control terminal 11 is placed at an isolation distance from the negative-side main terminal 13 on the outer surface of the switching element 10 on which the negative-side main terminal 13 is formed. That is, in the present embodiment, the main terminal 12, 13 (specifically, the negative-side main terminal 13) is formed on the first counter placement surface S2 of the switching element 10. In the present embodiment, the control terminal 11 is also formed on the first counter placement surface S2.

The switching element 10 is placed over the element placement surface S1 so that the first counter placement surface S2 and the element placement surface S1 contact each other directly or with a bonding member interposed therebetween. The element placement surface S1 that “contacts the element placement surface S1 directly or with the bonding member interposed therebetween” includes the electrodes formed on the element placement surface S1. Specifically, as shown in FIGS. 3 to 5, the upper stage-side switching element 10a is placed on the inter-element connection electrode P3 from above with a bonding material 93 interposed therebetween, and the upper stage-side diode element 20a is also placed on the inter-element connection electrode P3 from above with the bonding material 93 interposed therebetween. As shown in FIG. 5, in this example, the anode terminal 21 is formed on the lower surface of the diode element 20, and the cathode terminal 22 is formed on the upper surface of the diode element 20. That is, the diode element 20 is placed over the element placement surface S1 so that its outer surface having the anode terminal 21 formed thereon serves as a second counter placement surface S3 facing the element placement surface S1. The second counter placement surface S3 and the element placement surface S1 contact each other directly or with the bonding material interposed therebetween. The bonding material 93 as the bonding member is comprised of a conductive material such as, e.g., solder, conductive paste, etc. The negative-side main terminal 13 formed on the lower surface of the upper stage-side switching element 10a and the anode terminal 21 formed on the lower surface of the upper stage-side diode element 20a are thus electrically connected to the inter-element connection electrode P3.

The lower stage-side switching element 10b is placed on the negative-side connection electrode P2 from above with the bonding material 93 interposed therebetween, and the lower stage-side diode element 20b is also placed on the negative-side connection electrode P2 with the bonding material 93 interposed therebetween. The negative-side main terminal 13 formed on the lower surface of the lower stage-side switching element 10b and the anode terminal 21 formed on the lower surface of the lower stage-side diode element 20b are thus electrically connected to the negative-side connection electrode P2. The negative-side connection electrode P2 is electrically connected to the negative terminal 52, so that the negative-side main terminal 13 of the lower stage-side switching element 10b and the anode terminal 21 of the lower stage-side diode element 20b are electrically connected to the negative terminal 52 via the negative-side connection electrode P2. As described above, the negative-side connection electrode P2 is an electrode that electrically connects the negative-side terminal portion 32 of the first series element unit 30a which is formed by the anode terminal 21 of the lower stage-side diode element 20b and the negative-side terminal portion 32 of the second series element unit 30b which is formed by the negative-side main terminal 13 of the lower stage-side switching element 10b to the negative terminal 52 of the first smoothing capacitor 50.

As shown in FIGS. 1 and 2, a conductive first connection member 61 is placed so as to electrically connect the positive-side main terminal 12 (see FIGS. 4 and 5) formed on the upper surface of the upper stage-side switching element 10a and the cathode terminal 22 formed on the upper surface of the upper stage-side diode element 20a to the positive-side connection electrode P1. That is, the first connection member 61 electrically connects the positive-side connection electrode P1 and the upper stage-side switching element 10a, and electrically connects the positive-side connection electrode P1 and the upper stage-side diode element 20a. Specifically, as shown in FIG. 4, the first connection member 61 has a first portion 61a placed on the positive-side connection electrode P1 from above with the bonding material 93 interposed therebetween, and a second portion 61b placed on the upper stage-side switching element 10a and the upper stage-side diode element 20a from above with the bonding material 93 interposed therebetween. The positive-side main terminal 12 of the upper stage-side switching element 10a and the cathode terminal 22 of the upper stage-side diode element 20a are thus electrically connected to the positive-side connection electrode P1. The positive-side connection electrode P1 is electrically connected to the positive terminal 51, so that the positive-side main terminal 12 of the upper stage-side switching element 10a and the cathode terminal 22 of the upper stage-side diode element 20a are electrically connected to the positive terminal 51 via the positive-side connection electrode P1. The positive-side connection electrode P1 is thus an electrode that electrically connects the positive-side terminal portion 31 of the first series element unit 30a which is formed by the positive-side main terminal 12 of the upper stage-side switching element 10a and the positive-side terminal portion 31 of the second series element unit 30b which is formed by the cathode terminal 22 of the upper stage-side diode element 20a to the positive terminal 51 of the first smoothing capacitor 50.

As shown in FIGS. 1 and 2, a conductive second connection member 62 is placed so as to electrically connect the positive-side main terminal 12 (see FIG. 4) formed on the upper surface of the lower stage-side switching element 10b and the cathode terminal 22 formed on the upper surface of the lower stage-side diode element 20b to the inter-element connection electrode P3. That is, the second connection member 62 electrically connects the inter-element connection electrode P3 and the lower stage-side switching element 10b, and electrically connects the inter-element connection electrode P3 and the lower stage-side diode element 20b. Specifically, as shown in FIG. 4, the second connection member 62 has a first portion 62a placed on the inter-element connection electrode P3 from above with the bonding material 93 interposed therebetween, and a second portion 62b placed on the lower stage-side switching element 10b and the lower stage-side diode element 20b from above with the bonding material 93 interposed therebetween. The positive-side main terminal 12 of the lower stage-side switching element 10b and the cathode terminal 22 of the lower stage-side diode element 20b are thus electrically connected to the inter-element connection electrode P3. As a result, the negative-side main terminal 13 of the upper stage-side switching element 10a and the anode terminal 21 of the upper stage-side diode element 20a are electrically connected to the positive-side main terminal 12 of the lower stage-side switching element 10b and the cathode terminal 22 of the lower stage-side diode element 20b via the inter-element connection electrode P3. As described above, the inter-element connection electrode P3 is an electrode that electrically connects the switching element 10 and the diode element 20 of the series element unit 30 (specifically, the upper stage-side switching element 10a and the lower stage-side diode element 20b, and the upper stage-side diode element 20a and the lower stage-side switching element 10b) to form the intermediate connection portion 33, and is an electrode that connects the respective intermediate connection portions 33 of the plurality of series element units 30 of the same series element unit set 40.

In the present embodiment, as shown in FIG. 1, FIG. 4, etc., each of the first connection member 61 and the second connection member 62 has a flat portion on its upper surface. Although not shown in the figures, a heat sink is placed on this flat portion with an insulating member interposed therebetween. This insulating member has both electrical insulation properties and thermally conductive properties. This allows heat of the switching element 10 to be efficiently conducted to the heat sink via the connection member 61, 62 while ensuring electrical insulation between the switching element 10 and the heat sink. The connection members 61, 62 thus have a function as a heat spreader in addition to the function as a connection member (bus bar).

The control electrode P4 is a control electrode that is electrically connected to the control terminal 11. Specifically, as shown in FIG. 5, the control electrode P4 has a portion placed below the control terminal 11 and electrically connected thereto, and a portion (separated portion) separated from this portion in the −Y direction, and the gate resistor 83 is placed on these two portions from above so as to electrically connect these portions. Although not shown in the figures, a connection terminal of a flexible printed board is formed on the separated portion, and the control terminal 11 is electrically connected via the flexible printed board to the control unit (not shown) that produces a switching control signal (in this example, a gate drive signal). The flexible printed board is a printed board that is flexible and can be deformed to a large extent.

The discharge resistor electrode P5 is an electrode on which the discharge resistor 81 (see FIG. 7) electrically connected in parallel to the first smoothing capacitor 50 is placed. Specifically, as shown in FIG. 6, the discharge resistor electrode P5 has two portions that are separated from each other in the X direction, namely a portion electrically connected to the positive terminal 51 and a portion electrically connected to the negative terminal 52. As shown in FIG. 1, the discharge resistor 81 is placed on the two portions from above so as to electrically connect these portions.

### 2. Second Embodiment

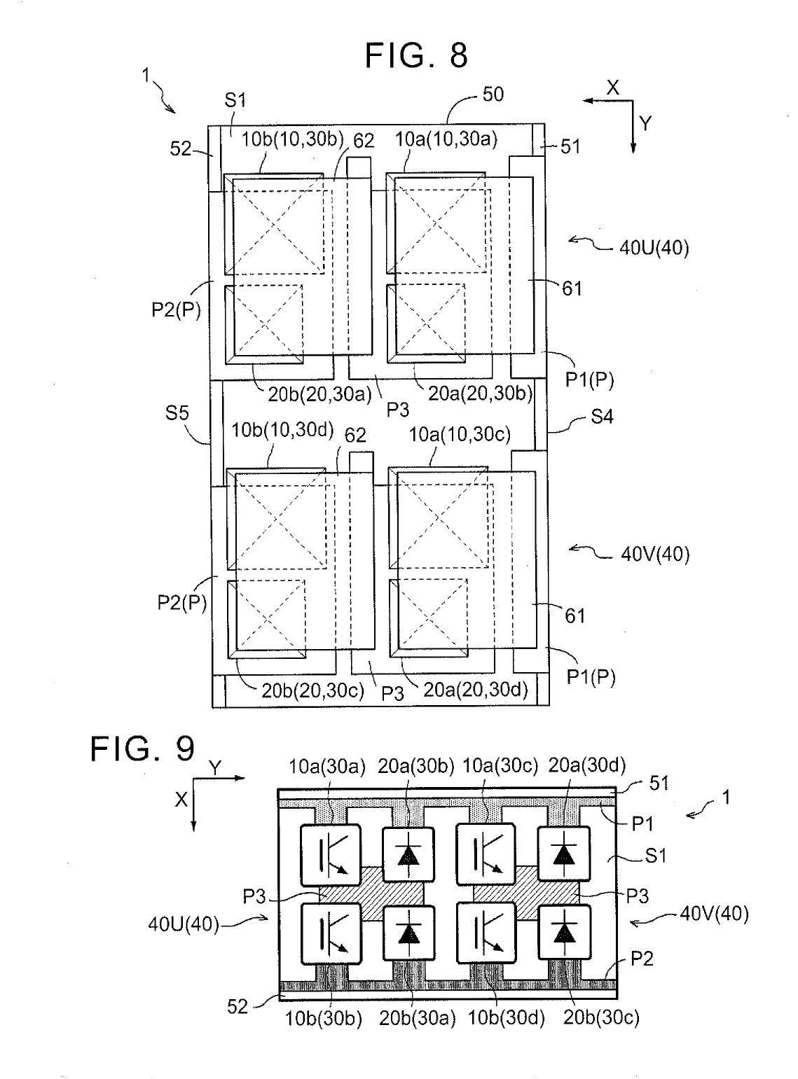

A second embodiment will be described with reference to FIGS. 8 to 10. A switching element unit 1 according to the present embodiment is different from the first embodiment in that the switching element unit 1 of the present embodiment includes a plurality of series element unit sets 40. Two specific examples according to the present embodiment will be sequentially described below. In the present embodiment and third and fourth embodiments described below, differences from the first embodiment will be mainly described, and these embodiments are similar to the first embodiment in those points that are not specifically mentioned.

### 2-1. First Specific Example

As shown in FIG. 8, in a first specific example, the switching element unit 1 includes two series element unit sets 40. Specifically, the switching element unit 1 includes the V-phase series element unit set 40V in addition to the U-phase series element unit set 40U. As shown in FIG. 7, the V-phase series element unit set 40V is configured similarly to the U-phase series element unit set 40U except the phase of the coil to which the intermediate connection portions 33 are connected. That is, a third series element unit 30c of the V-phase series element unit set 40V is configured similarly to the first series element unit 30a of the U-phase series element unit set 40U, and a fourth series element unit 30d of the V-phase series element unit set 40V is configured similarly to the second series element unit 30b of the U-phase series element unit set 40U.

As shown in FIG. 8, the V-phase series element unit set 40V is placed on the +Y direction side with respect to the U-phase series element unit set 40U so as to be located next to the U-phase series element unit set 40U. That is, the switching element unit 1 according to this specific example has a configuration in which two switching element units 1 (see FIG. 3) according to the first embodiment are arranged side by side in the Y direction. Those portions which are associated with the discharge resistor 81 and the gate resistor 83 are not shown in FIG. 8 in order to avoid complication. In this configuration, a single first smoothing capacitor 50 is electrically connected in parallel to the two arm sets (two series element unit sets 40). Accordingly, capacitance of the first smoothing capacitor 50 in this example is twice that of the first embodiment.

FIG. 9 is a schematic diagram showing in a simplified manner the switching element unit 1 according to this specific example shown in FIG. 8. FIG. 9 and FIGS. 10 to 21 which will be referred to later are diagrams illustrating the positional relationship between the elements 10, 20 on the element placement surface S1, and the positional relationship among the electrodes P1, P2, P3 on the element placement surface S1 which is determined according to the positional relationship between the elements 10, 20. Accordingly, in order to facilitate understanding of these positional relationships, the connection members 61, 62 are not shown in FIGS. 9 to 21, and the shapes of the elements 10, 20 and the electrodes P1, P2, P3 are schematically shown in FIGS. 9 to 21.

### 2-2. Second Specific Example

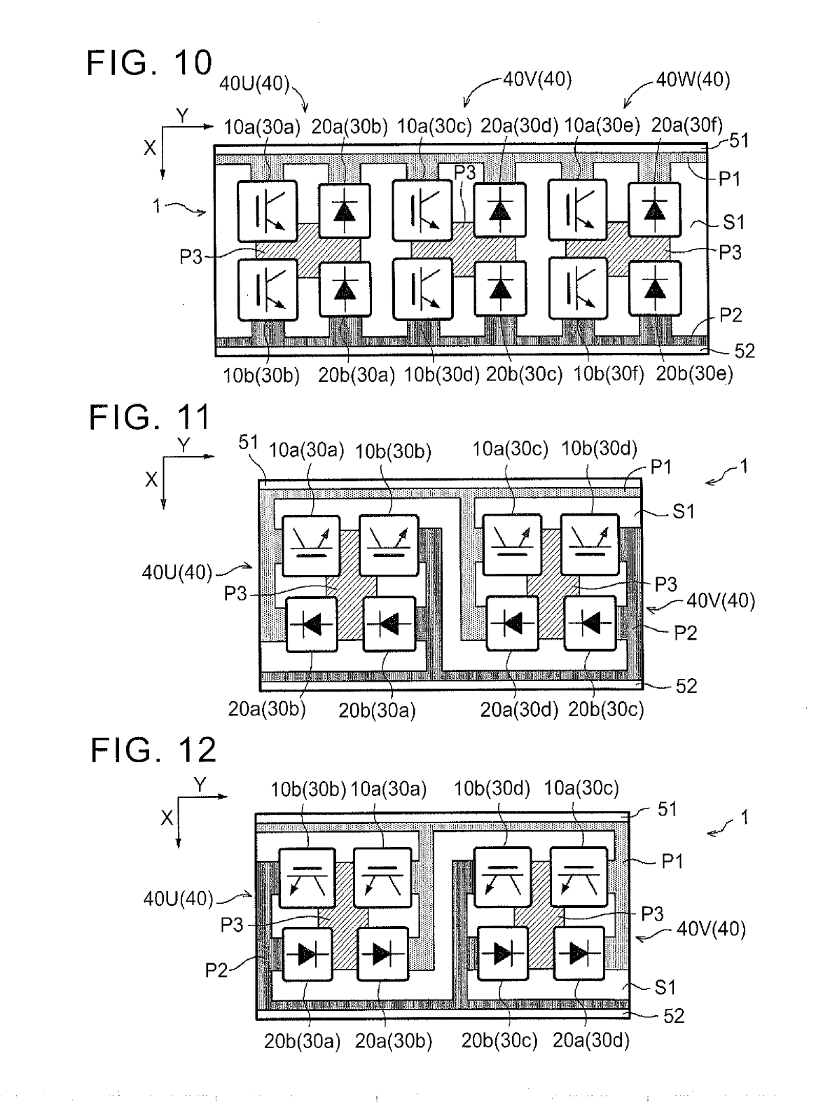

As shown in FIG. 10, unlike the first specific example, a switching element unit 1 in a second specific example includes three series element unit sets 40. Specifically, the switching element unit 1 includes the W-phase series element unit set 40W in addition to the U-phase series element unit set 40U and the V-phase series element unit set 40V. As shown in FIG. 7, the W-phase series element unit set 40W is configured similarly to the U-phase series element unit set 40U except the phase of the coil to which the intermediate connection portions 33 are connected. That is, a fifth series element unit 30e of the W-phase series element unit set 40W is configured similarly to the first series element unit 30a of the U-phase series element unit set 40U, and a sixth series element unit 30f of the W-phase series element unit set 40W is configured similarly to the second series element unit 30b of the U-phase series element unit set 40U. In this configuration, a single first smoothing capacitor 50 is electrically connected in parallel to the three arm sets (three series element unit sets 40). Accordingly, capacitance of the first smoothing capacitor 50 in this example is three times that of the first embodiment.

In the first specific example (FIG. 9) and the second specific example (FIG. 10), the arrangement relationship among the upper stage-side switching element 10a, the lower stage-side switching element 10b, the upper-stage side diode element 20a, and the lower stage-side diode element 20b on the element placement surface S1 is the same between the different series element unit sets 40. However, this arrangement relationship may vary between the different series element unit sets 40. For example, the V-phase series element unit set 40V according to the specific example shown in FIG. 9 may be configured so that the upper stage-side switching element 10a and the upper stage-side diode element 20a are switched, so that the lower stage-side switching element 10b and the lower stage-side diode element 20b are switched, or so that the upper stage-side switching element 10a and the upper stage-side diode element 20a are switched and the lower stage-side switching element 10b and the lower stage-side diode element 20b are switched. Similar switching can be implemented in each specific example described below.

### 3. Third Embodiment

A third embodiment will be described with reference to FIGS. 11 to 18. A switching element unit 1 according to the present embodiment is different from the first and second embodiments in that regarding at least one series element unit set 40 included in the switching element unit 1 of the present embodiment, each of the plurality of positive-side elements included in the series element unit set 40 is placed on the same side in the Y direction with respect to the negative-side element of the same series element unit 30. The switching element unit 1 according to the present embodiment is also different from the first and second embodiments in that regarding at least one series element unit set 40 included in the switching element unit 1 of the present embodiment, each of the plurality of switching elements 10 included in the series element unit set 40 is placed on the same side in the X direction with respect to the diode element 20 of the same series element unit 30. Eight specific examples according to the present embodiment will be sequentially described below.

### 3-1. First Specific Example

As shown in FIG. 11, in a first specific example, the switching element unit 1 includes two series element unit sets 40 (the U-phase series element unit set 40U and the V-phase series element unit set 40V). In this specific example, the arrangement relationship of the upper stage-side switching element 10a, the lower stage-side switching element 10b, the upper stage-side diode element 20a, and the lower stage-side diode element 20b are the same between the U-phase series element unit set 40U and the V-phase series element unit set 40V. Accordingly, only the U-phase series element unit set 40U will be described below.

As shown in FIG. 11, the upper stage-side switching element 10a as the positive-side element of the first series element unit 30a is placed on the −Y direction side with respect to the lower stage-side diode element 20b as the negative-side element of the first series element unit 30a, and the upper stage-side diode element 20a as the positive-side element of the second series element unit 30b is placed on the −Y direction side with respect to the lower stage-side switching element 10b as the negative-side element of the second series element unit 30b. That is, each of the plurality of positive-side elements included in the U-phase series element unit set 40U is placed on the −Y direction side with respect to the negative-side element of the same series element unit 30. In this specific example, regarding each of all the series element unit sets 40 included in the switching element unit 1, each of the plurality of positive-side elements included in the series element unit set 40 is placed on the same side in the Y direction with respect to the negative-side element of the same series element unit 30.

In this specific example, the positive-side element is placed on the −X direction side with respect to the negative-side element in the first series element unit 30a, whereas the positive-side element is placed on the +X direction side with respect to the negative-side element in the second series element unit 30b. That is, the upper stage-side switching element 10a is placed on the −X direction side with respect to the lower stage-side diode element 20b, and the lower stage-side switching element 10b is placed on the −X direction side with respect to the upper stage-side diode element 20a. In this specific example, each of the plurality of switching elements 10 included in the same series element unit set 40 is placed on the same side in the X direction with respect to the diode element 20 of the same series element unit 30. The plurality of switching elements 10 included in the same series element unit set 40 (in this example, the upper stage-side switching element 10a and the lower stage-side switching element 10b) are arranged side by side in the Y direction over the element placement surface S1.

As shown in FIG. 11, in this specific example as well, the positive-side connection electrode P1 does not have a portion placed on the +X direction side of the negative-side connection electrode P2, along the entire length in the Y direction of the element placement surface S1, as in the first and second embodiments. That is, the positive-side connection electrode P1 does not have a portion placed between the negative terminal 52 and the negative-side connection electrode P2 in the X direction, along the entire length in the Y direction of the element placement surface S1. In this specific example, the positive-side connection electrode P1 has a portion extending in the X direction on the −Y direction side with respect to the inter-element connection electrode P3, and the negative-side connection electrode P2 has a portion extending in the X direction on the +Y direction side with respect to the inter-element connection electrode P3. Accordingly, in this specific example, unlike the first and second embodiments, the inter-element connection electrode P3 is formed between the positive-side connection electrode P1 and the negative-side connection electrode P2 in the Y direction on the element placement surface S1. That is, unlike the first and second embodiments, the positive-side connection electrode P1, the negative-side connection electrode P2, and the inter-element connection electrode P3 are formed so as to have a portion where the electrodes P1, P2, P3 overlap each other, as viewed in the Y direction.

### 3-2. Second Specific Example

As shown in FIG. 12, a second specific example corresponds to a configuration in which the upper stage-side switching element 10a and the lower stage-side switching element 10b are switched and the upper stage-side diode element 20a and the lower stage-side diode element 20b are switched in each series element unit set 40 in the first specific example (FIG. 11). That is, in this specific example, unlike the first specific example, each of the plurality of positive-side elements included in the U-phase series element unit set 40U is placed on the +Y direction side with respect to the negative-side element of the same series element unit 30. In this specific example, unlike the first specific example, the positive-side connection electrode P1 has a portion extending in the X direction on the +Y direction side with respect to the inter-element connection electrode P3, and the negative-side connection electrode P2 has a portion extending in the X direction on the −Y direction side with respect to the inter-element connection electrode P3.

### 3-3. Third Specific Example

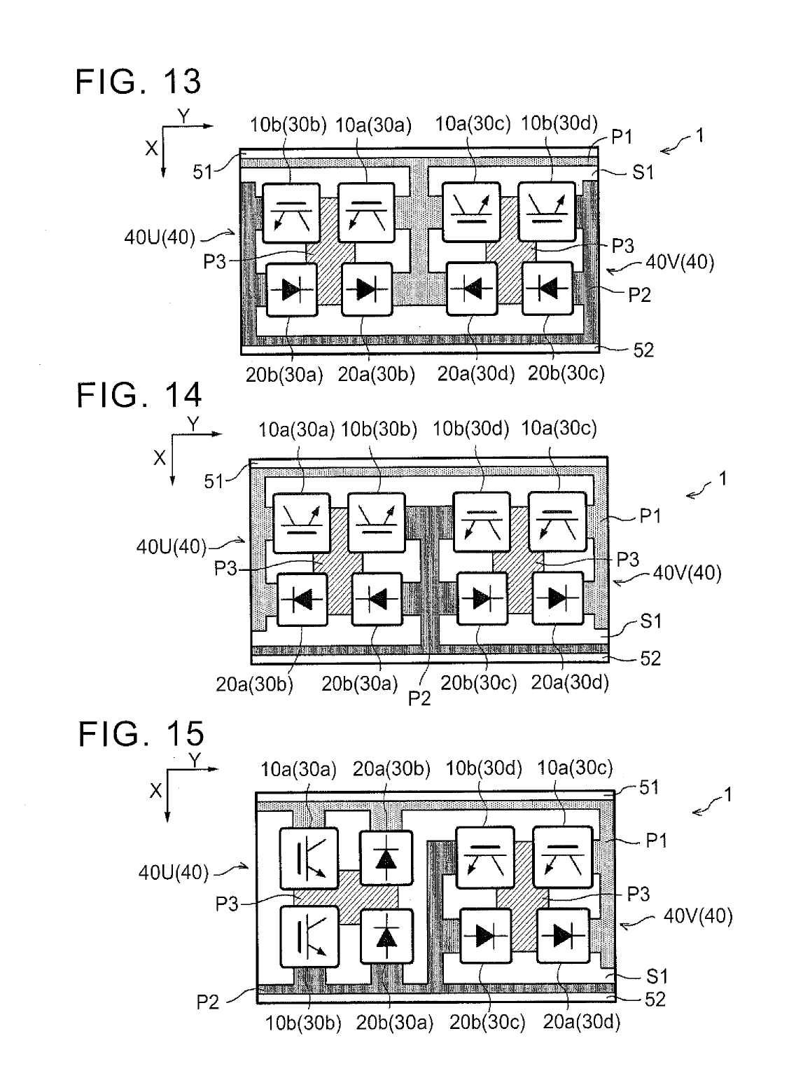

As shown in FIG. 13, a third specific example corresponds to a configuration in which the V-phase series element unit set 40V in the first specific example (FIG. 11) is combined with the U-phase series element unit set 40U in the second specific example (FIG. 12). That is, in this specific example, the arrangement relationship of the upper stage-side switching element 10a, the lower stage-side switching element 10b, the upper stage-side diode element 20a, and the lower stage-side diode element 20b over the element placement surface S1 is different between the different series element unit sets 40.

### 3-4. Fourth Specific Example

As shown in FIG. 14, a fourth specific example corresponds to a configuration in which the U-phase series element unit set 40U in the first specific example (FIG. 11) is combined with the V-phase series element unit set 40V in the second specific example (FIG. 12).

### 3-5. Fifth Specific Example

As shown in FIG. 15, a fifth specific example corresponds to a configuration in which the U-phase series element unit set 40U in the first specific example (FIG. 9) according to the second embodiment is combined with the V-phase series element unit set 40V in the second specific example (FIG. 12) according to the present embodiment. In this specific example, regarding at least one of the series element unit sets 40 included in the switching element unit 1 (specifically, the V-phase series element unit set 40V), each of the plurality of positive-side elements included in the series element unit set 40 is placed on the same side in the Y direction with respect to the negative-side element of the same series element unit 30.

### 3-6. Sixth Specific Example

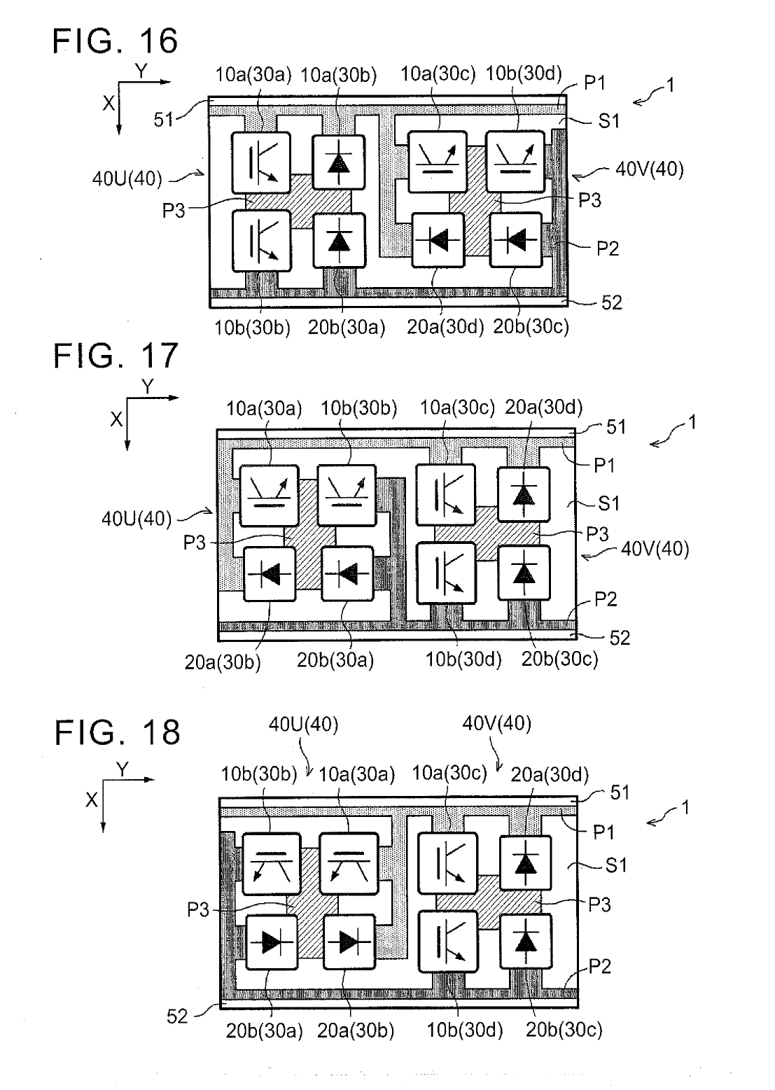

As shown in FIG. 16, a sixth specific example corresponds to a configuration in which the U-phase series element unit set 40U in the first specific example (FIG. 9) according to the second embodiment is combined with the V-phase series element unit set 40V in the first specific example (FIG. 11) according to the present embodiment.

### 3-7. Seventh Specific Example

As shown in FIG. 17, a seventh specific example corresponds to a configuration in which the V-phase series element unit set 40V in the first specific example (FIG. 9) according to the second embodiment is combined with the U-phase series element unit set 40U in the first specific example (FIG. 11) according to the present embodiment.

### 3-8. Eighth Specific Example

As shown in FIG. 18, an eighth specific example corresponds to a configuration in which the V-phase series element unit set 40V in the first specific example (FIG. 9) according to the second embodiment is combined with the U-phase series element unit set 40U in the second specific example (FIG. 12) according to the present embodiment.

### 4. Fourth Embodiment

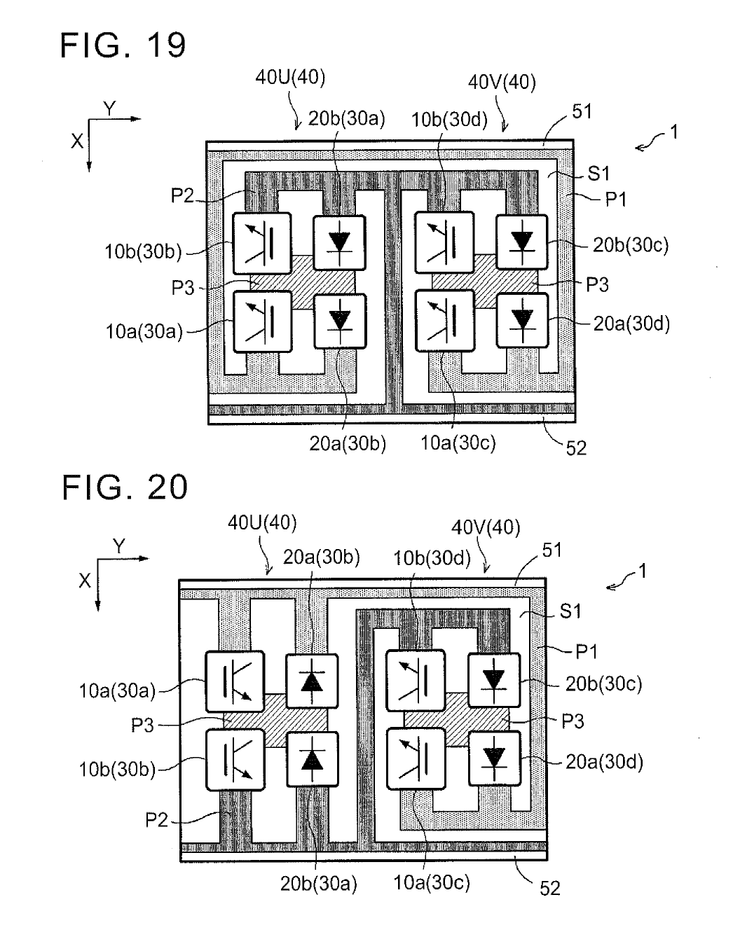

A fourth embodiment will be described with reference to FIGS. 19 to 21. A switching element unit 1 according to the present embodiment is different from the first to third embodiments in that regarding at least one series element unit set 40 included in the switching element unit 1 of the present embodiment, the positive-side connection electrode P1 has a portion that is placed between the negative terminal 52 and the negative-side connection electrode P2 in the X direction. Three specific examples according to the present embodiment will be sequentially described below.

### 4-1. First Specific Example

As shown in FIG. 19, in a first specific example, the switching element unit 1 includes two series element unit sets 40 (the U-phase series element unit set 40U and the V-phase series element unit set 40V), and regarding every series element unit 30, the positive-side terminal is placed on the +X direction side with respect to the negative-side terminal (i.e., on the negative terminal 52 side in the X direction). Because of such an arrangement configuration, regarding each of the two series element unit sets 40 in this specific example, the positive-side connection electrode P1 has a portion that is placed on the +X direction side of the negative-side connection electrode P2, as shown in FIG. 19. That is, the positive-side connection electrode P1 has a portion that is placed between the negative terminal 52 and the negative-side connection electrode P2 in the X direction.

### 4-2. Second Specific Example

As shown in FIG. 20, a second specific example corresponds to a configuration in which the U-phase series element unit set 40U in the first specific example (FIG. 9) according to the second embodiment is combined with the V-phase series element unit set 40V in the first specific example (FIG. 19) according to the present embodiment. That is, in this specific example, regarding at least one of the series element unit sets 40 included in the switching element unit 1, the positive-side connection electrode P1 has a portion that is placed between the negative terminal 52 and the negative-side connection electrode P2 in the X direction.

### 4-3. Third Specific Example

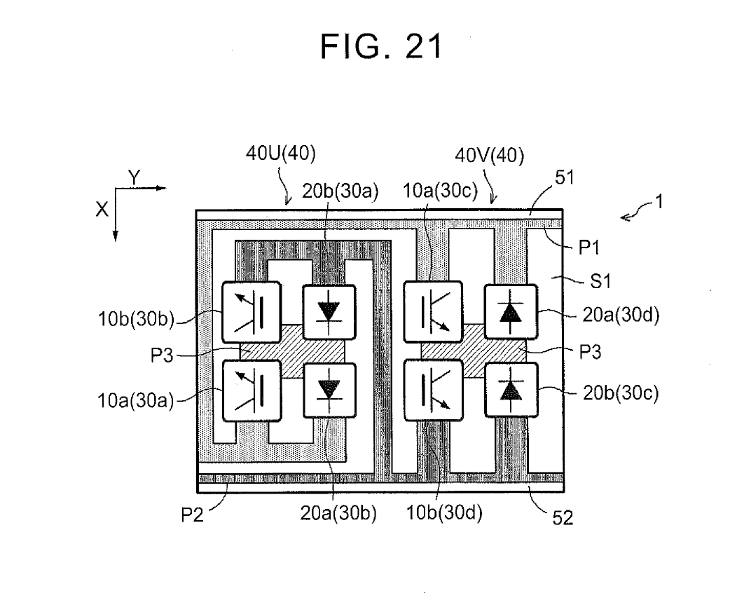

As shown in FIG. 21, a third specific example corresponds to a configuration in which the V-phase series element unit set 40V in the first specific example (FIG. 9) according to the second embodiment is combined with the U-phase series element unit set 40U in the first specific example (FIG. 19) according to the present embodiment.

### 5. Other Embodiments

Lastly, other embodiments of the switching element unit will be described. The configuration disclosed in each of the following embodiments and the configuration disclosed in each of the above embodiments may be applied in combination with the configurations disclosed in the other embodiments as long as no inconsistency arises.

(1) Each of the above embodiments is described with respect to an example in which the element placement surface S1 is formed of the same material as the dielectric portions 53. However, embodiments of the present invention are not limited to this, and the element placement surface S1 may be formed of a different material from the dielectric portions 53. Each of the above embodiments is described with respect to an example in which an even number of series element units 30 are placed over the element placement surface S1. However, an odd number of (e.g., one, three, etc.) series element units 30 may be placed over the element placement surface S1.

(2) Each of the above embodiments is described with respect to an example in which the control terminal 11 is formed on the first counter placement surface S2 of the switching element 10. However, embodiments of the present invention are not limited to this, and the control terminal 11 may be formed on the outer surface of the switching element 10 other than the first counter placement surface S2 (e.g., the upper surface as the upper outer surface). In this case, for example, the control terminal may be electrically connected to the control electrode P4 via a wire member. In this case, the control electrode P4 may not be formed on the element placement surface S1, and the control terminal 11 may be electrically connected to the control unit (not shown) that produces a switching control signal (in this example, a gate drive signal) without via the element placement surface S1.

(3) Each of the above embodiments is described with respect to an example in which the diode element electrically connected in parallel to the switching element 10 is placed over the element placement surface S1 so as to adjoin this switching element 10. However, embodiments of the present invention are not limited to this, and some other circuit element may be placed between the switching element 10 and the diode element 20 which are electrically connected in parallel to each other, in the direction in which the element placement surface S1 extends.

(4) Each of the above embodiments is described with respect to an example in which the inverter circuit 91 is a DC-to-AC converter circuit that converts a DC voltage to a three-phase AC voltage and the inverter circuit 91 includes six switching elements 10. However, embodiments of the present invention are not limited to this, and the inverter circuit 91 may be a DC-to-AC converter circuit that converts a DC voltage to a single-phase AC voltage and the inverter circuit 91 may include four switching elements 10.

(5) Each of the above embodiments is described with respect to an example in which the switching element unit according to exemplary embodiments is applied to the inverter circuit 91 (see FIG. 7) that controls the rotating electrical machine 2. However, embodiments of the present invention are not limited to this, and the switching element unit according to the present invention may be applied to other circuits such as the booster circuit 92. In the case where the switching element unit according to the present invention is applied to the booster circuit 92, for example, an element placement surface may be formed on the outer surface of the second smoothing capacitor 60, and series element units that are formed by the switching elements 10 and the diode elements 20 of the booster circuit 92 may be placed over this element placement surface. Although detailed description is omitted, this configuration can be implemented similarly to the above embodiments except that the element placement surface S1 in the above embodiments is replaced with the element placement surface of the second smoothing capacitor 60.

(6) Each of the above embodiments is described with respect to an example in which the rotating electrical machine drive circuit that drives the rotating electrical machine 2 includes the booster circuit 92 in addition to the inverter circuit 91. However, embodiments of the present invention are not limited to this, and the rotating electrical machine drive circuit that drives the rotating electrical machine 2 may not include the booster circuit 92.

(7) Regarding other configurations as well, the embodiments disclosed in the specification are by way of example only in all respects, and embodiments of the present invention are not limited to them. That is, those configurations which are not described in the claims of the present application can be modified as appropriate without departing from the object of the present invention.

### III. INDUSTRIAL APPLICABILITY

The present invention can be preferably used for switching element units including a switching element and a diode element.

### DESCRIPTION OF THE REFERENCE NUMERALS

1: Switching Element Unit
10: Switching Element
20: Diode Element
30: Series Element Unit
31: Positive-Side Terminal Portion
32: Negative-Side Terminal Portion
33: Intermediate Connection Portion
40: Series Element Unit Set
50: First Smoothing Capacitor (Smoothing Capacitor)
51: Positive Terminal
52: Negative Terminal
53: Dielectric Portion
54a: Positive-Side Internal Electrode
54b: Negative-Side Internal Electrode
P1: Positive-Side Connection Electrode
P2: Negative-Side Connection Electrode
P3: Inter-Element Connection Electrode
S1: Element Placement Surface
S4: First Planar Surface
S5: Second Planar Surface
X: Reference Direction
Y: Reference Perpendicular Direction

1-7. (canceled)

8. A switching element unit, comprising:
a series element unit made up of at least one set of a switching element and a diode element which are electrically connected in series to each other; and
a smoothing capacitor configured to suppress fluctuation in DC voltage to be supplied to the series element unit, wherein
the smoothing capacitor is a ceramic capacitor whose dielectric portion interposed between electrodes is formed of a ceramic material,
outer surfaces of the smoothing capacitor include an element placement surface formed integrally with the dielectric portion,
a first planar surface crossing the element placement surface at an end of the element placement surface which is located on one side in a reference direction that is set along the element placement surface, and
a second planar surface crossing the element placement surface at an end of the element placement surface which is located on an other side in the reference direction, a positive terminal of the smoothing capacitor is formed on the first planar surface, and a negative terminal of the smoothing capacitor is formed on the second planar surface,
a positive-side connection electrode that is electrically connected to the positive terminal and a negative-side connection electrode that is electrically connected to the negative terminal are formed on the element placement surface, and
the switching element and the diode element of the series element unit are placed over the element placement surface, a positive-side terminal portion of the series element unit is electrically connected to the positive-side connection electrode, and a negative-side terminal portion of the series element unit is electrically connected to the negative-side connection electrode.

9. The switching element unit according to claim 8, wherein
a positive-side internal electrode extending from the positive terminal to the negative terminal side in the reference direction and a negative-side internal electrode extending from the negative terminal to the positive terminal side in the reference direction are formed in the smoothing capacitor.

10. The switching element unit according to claim 9, wherein
a direction perpendicular to the reference direction along the element placement surface is a reference perpendicular direction, and
the positive-side connection electrode is configured so as not to have a portion that is placed between the negative terminal and the negative-side connection electrode in the reference direction, along an entire length in the reference perpendicular direction of the element placement surface.

11. The switching element unit according to claim 10, wherein
a connection portion between the switching element and the diode element of the series element unit is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the switching elements included in a same series element unit set is placed on a same side in the reference direction or on a same side in the reference perpendicular direction with respect to the diode element forming the same series element unit.

12. The switching element unit according to claim 11, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

13. The switching element unit according to 11, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in the same series element unit set is placed on the same side in the reference perpendicular direction with respect to the negative-side element forming the same series element unit.

14. The switching element unit according to 13, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.

15. The switching element unit according to claim 9, wherein
a connection portion between the switching element and the diode element of the series element unit is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the switching elements included in a same series element unit set is placed on a same side in the reference direction or on a same side in the reference perpendicular direction with respect to the diode element forming the same series element unit.

16. The switching element unit according to claim 15, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

17. The switching element unit according to claim 15, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in the same series element unit set is placed on the same side in the reference perpendicular direction with respect to the negative-side element forming the same series element unit.

18. The switching element unit according to claim 15, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.

19. The switching element unit according to claim 9, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

20. The switching element unit according to claim 9, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in a same series element unit set is placed on a same side in the reference perpendicular direction with respect to the negative-side element forming the same series element unit.

21. The switching element unit according to claim 9, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.

22. The switching element unit according to claim 8, wherein
a direction perpendicular to the reference direction along the element placement surface is a reference perpendicular direction, and
the positive-side connection electrode is configured so as not to have a portion that is placed between the negative terminal and the negative-side connection electrode in the reference direction, along an entire length in the reference perpendicular direction of the element placement surface.

23. The switching element unit according to claim 22, wherein
a connection portion between the switching element and the diode element of the series element unit is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the switching elements included in a same series element unit set is placed on a same side in the reference direction or on a same side in the reference perpendicular direction with respect to the diode element forming the same series element unit.

24. The switching element unit according to claim 23, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

25. The switching element unit according to 23, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in the same series element unit set is placed on the same side in the reference perpendicular direction with respect to the negative-side element forming the same series element unit.

26. The switching element unit according to claim 23, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.

27. The switching element unit according to claim 22, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

28. The switching element unit according to claim 22, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in a same series element unit set is placed on a same side in the reference perpendicular direction with respect to the negative-side element forming the same series element unit.

29. The switching element unit according to 22, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.

30. The switching element unit according to claim 8, wherein
a connection portion between the switching element and the diode element of the series element unit is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the switching elements included in a same series element unit set is placed on a same side in the reference direction or on a same side in the reference perpendicular direction with respect to the diode element forming the same series element unit.

31. The switching element unit according to claim 22, wherein
a positive-side element placed on a positive side, which is one of the switching element and the diode element of the series element unit, is placed on the positive terminal side in the reference direction with respect to a negative-side element placed on a negative side, which is an other of the switching element and the diode element of the series element unit.

32. The switching element unit according to claim 22, wherein
a connection portion between a positive-side element placed on a positive side, which is one of the switching element and the diode element of the series element unit, and a negative-side element placed on a negative side, which is an other of the switching element and the diode element of the series element unit, is an intermediate connection portion,
the respective intermediate connection portions of a plurality of the series element units are electrically connected together to form a series element unit set,
a direction perpendicular to the reference direction along the element placement surface is a reference perpendicular direction, and
each of a plurality of the positive-side elements included in a same series element unit set is placed on a same side in the reference perpendicular direction with respect to the negative-side element forming the same series element unit.

33. The switching element unit according to claim 22, wherein
the positive-side connection electrode is formed so as to extend from the positive terminal to the negative terminal side in the reference direction on the element placement surface,
the negative-side connection electrode is formed so as to extend from the negative terminal to the positive terminal side in the reference direction on the element placement surface, and
an inter-element connection electrode that electrically connects the switching element and the diode element of the series element unit is formed between the positive-side connection electrode and the negative-side connection electrode in the reference direction on the element placement surface.
